(19) United States
(12) Patent Application Publication
(10) Pub. No.: US 2019/0265300 A1
(43) Pub. Date: Aug. 29, 2019

(54) BATTERY DEVICE AND CHARGING END DETECTING METHOD

(71) Applicant: DENSO TEN Limited, Kobe-shi (JP)

(72) Inventor: Yoshinori NAGAOKA, Kobe-shi (JP)

(73) Assignee: DENSO TEN Limited, Kobe-shi (JP)

(21) Appl. No.: 16/156,169

(22) Filed: Oct. 10, 2018

(30) Foreign Application Priority Data
Feb. 23, 2018 (JP) 2018-031155

(51) Int. Cl. G01R 31/36; H02J 7/00

(52) U.S. Cl. CPC G01R 31/362; H02J 2007/0059; H02J 7/0052

(57) ABSTRACT

A battery device includes a connection part to which a charging plug of charging equipment is connected; a monitoring unit configured to monitor connection voltage varying gradually according to a connection state between the connection part and the charging plug; and a detecting unit configured to detect an end of charging of a battery on the basis of the connection voltage which is monitored by the monitoring unit.

### CROSS-REFERENCE TO RELATED APPLICATIONS

This application is based on and claims priority under 35 U.S.C. § 119 from Japanese Patent Application No. 2018-31155 filed on Feb. 23, 2018.

### BACKGROUND

### Technical Field

The present disclosure relates to a battery device and a charging end detecting method.

### Related Art

In the related art, there are battery devices which can be mounted on electric vehicles and so on. Such a battery device detects the end of charging on the basis of an end notification sent from charging equipment, and starts a charging finishing process (see Patent Literature 1 for instance).

[Patent Literature 1] Japanese Patent Application Laid-Open No. 2012-034506

However, in the technology of the related art, if any notification is not sent from the charging equipment, it is impossible to detect the end of charging, and it is impossible to start a charging finishing process.

It is therefore an object of the present disclosure to provide a battery device and a charging end detecting method capable of detecting the end of charging.

### SUMMARY

According to an aspect of the present disclosure, there is provided a battery device including: a connection part to which a charging plug of charging equipment is connected; a monitoring unit configured to monitor connection voltage varying gradually according to a connection state between the connection part and the charging plug; and a detecting unit configured to detect an end of charging of a battery on the basis of the connection voltage which is monitored by the monitoring unit.

According to the present disclosure, it is possible to detect the end of charging.

### BRIEF DESCRIPTION OF THE DRAWINGS

Exemplary embodiment of the present invention will be described in detail based on the following figures, wherein:

FIG. 1 is a view illustrating an outline of a charging end detecting method;

FIG. 2 is a block diagram of a charging system;

FIG. 3A is a view illustrating a specific example of a connection state;

FIG. 3B is a view illustrating another specific example of the connection state;

FIG. 4 is a view illustrating the relation between connection voltage and the connection state; and

FIG. 5 is a flow chart illustrating a process procedure which is performed by charging equipment.

### DETAILED DESCRIPTION

Hereinafter, a battery device and a charging end detecting method according to an embodiment will be described in detail with reference to the accompanying drawings. However, the present invention is not limited by the following embodiment.

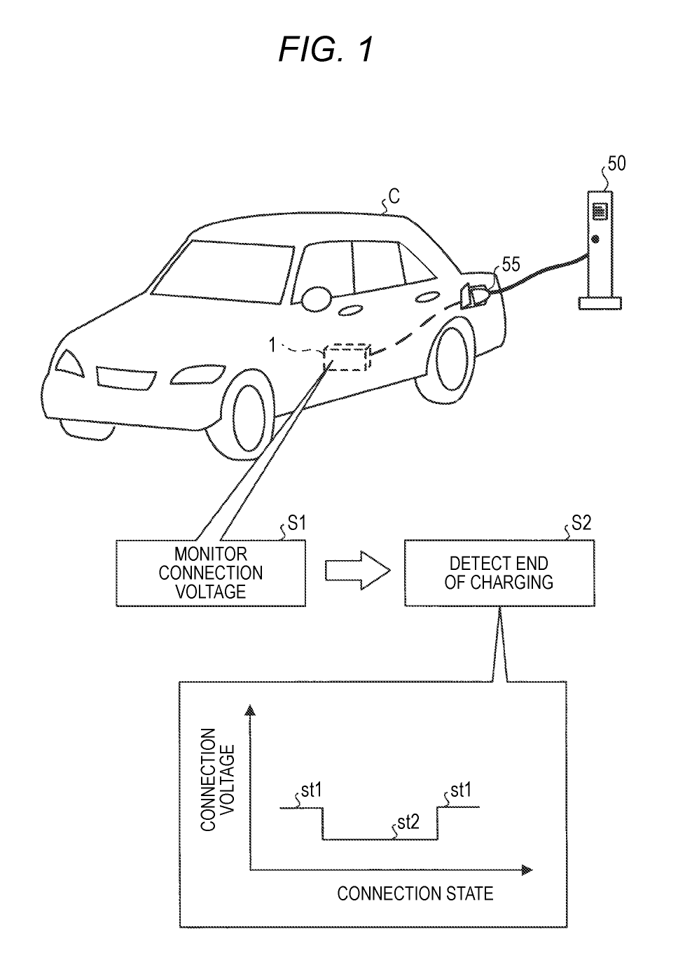

First, an outline of the charging end detecting method according to the embodiment will be described with reference to FIG. 1. FIG. 1 is a view illustrating the outline of the charging end detecting method. The charging end detecting method is performed by a battery device 1 shown in FIG. 1.

As shown in FIG. 1, the battery device 1 is mounted on a vehicle C. The vehicle C is a so-called plug-in vehicle which is driven by electric power stored in the battery device 1.

The battery device 1 is charged by charging equipment 50. The charging equipment 50 is a charging station for charging the battery device 1. The charging equipment 50 has a charging plug 55, which is connected to the battery device 1 such that electric power which is supplied from the charging equipment 50 can be stored in the battery device via the charging plug 55.

By the way, in the technology of the related art, the battery device detects the end of charging on the basis of a charging end notification which is sent from the charging equipment. If detecting the end of charging, the battery device switches off a relay connecting a battery and a connection part to which a charging plug is connected. In this way, the battery and the connection part are electrically disconnected from each other. Therefore, it is possible to release the connection part from the high-voltage state.

However, in the technology of the related art, in the case where any end notification is not sent from the charging equipment side, the battery device cannot detect the end of charging. For example, if the charging plug is pulled out before the battery and the connection part are electrically disconnected from each other, the user may get an electric shock via the connection part which is in the high-voltage state and the charging plug.

For this reason, the charging end detecting method according to the embodiment detects the end of charging on the battery device side. As a result, it becomes possible to release the connection part from the high-voltage state, even in the case where the end of charging is not notified from the charging equipment side.

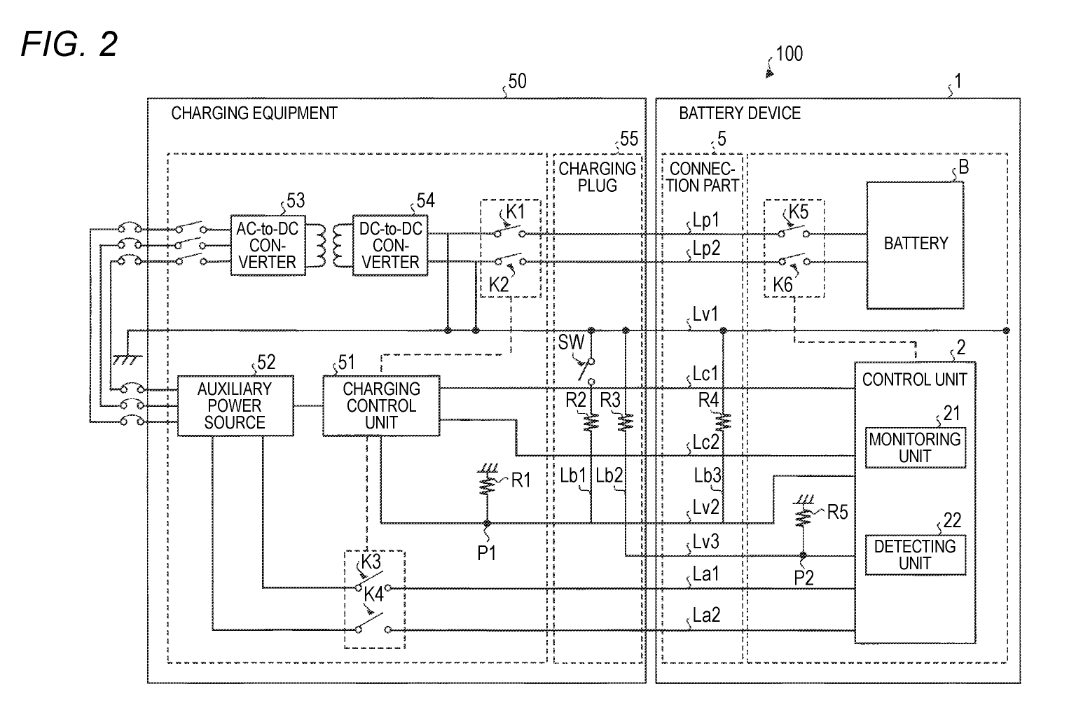

Specifically, as shown in FIG. 1, first, the charging end detecting method according to the embodiment monitors connection voltage (STEP S1). Here, the connection voltage is voltage varying according to the connection state between a connection part 5 (see FIG. 2) and the charging plug 55.

Examples of the connection state include an insertion state st1 and a lock state st2. The insertion state st1 is a state where the charging plug 55 has been inserted in the connection part 5. The lock state st2 is a state where the charging plug 55 has been locked by a mechanical locking mechanism to prevent the charging plug 55 from falling out of the connection part 5 after the insertion state st1. For example, the locking mechanism is switched on and off by user's operations on the charging plug 55.

In the case of charging the battery device 1, the connection state first transitions to the insertion state st1, and then transitions to the lock state st2, and in the lock state st2, electric power from the charging equipment 50 is stored in the charging equipment 50.

Meanwhile, in the case of finishing charging the battery device 1, the connection state transitions from the lock state st2 to the insertion state st1, and then the charging plug 55 is pulled out from the connection part 5.

For this reason, the charging end detecting method according to the embodiment detects the end of charging on the basis of change in the connection voltage which occurs when the connection state changes from the lock state st2 to the insertion state st1 (STEP S2).

In other words, the charging end detecting method according to the embodiment detects unlocking which is performed by the user, on the basis of the connection voltage, and detects such unlocking as the end of charging.

Therefore, according to the charging end detecting method of the embodiment, it becomes possible to detect the end of charging on the battery device (1) side even in the case where the end of charging is not notified from the charging equipment 50.

Now, a specific example of a charging system 100 according to the embodiment will be described with reference to FIG. 2. FIG. 2 is a block diagram of the charging system 100. Further, FIG. 2 shows a state where the battery device 1 and the charging equipment 50 have been connected, and shows the case where the connection state is the above-mentioned insertion state st1. As shown in FIG. 2, the charging system 100 according to the embodiment includes the battery device 1 and the charging equipment 50.

Further, as shown in FIG. 2, for example, the battery device 1 and the charging equipment 50 are connected by power lines Lp1 and Lp2, voltage lines Lv1 to Lv3, signal lines Lc1 and Lc2, and auxiliary power lines La1 and La2.

The power line Lp1 and the power line Lp2 are lines for supplying electric power from the charging equipment 50 to the battery device 1, and have a relay K1 and a relay K2 on the charging equipment (50) side, and have a relay K5 and a relay K6 on the battery device (1) side.

The switching on or off of the relay K1 and the relay K2 provided on the charging equipment (50) side is controlled by the charging control unit 51, and the switching on or off of the relay K5 and the relay K6 provided on the battery device (1) side is controlled by a control unit 2 of the battery device 1.

The voltage lines Lv1 to Lv3 are lines to which voltage for detecting the connection state between the battery device 1 and the charging equipment 50 is applied. The voltage line Lv1 branches off from the power line Lp1 and the power line Lp2 mentioned above, and a predetermined voltage (for example, 12 V) on the power line Lp1 and the power line Lp2 is applied thereto.

Also, the voltage line Lv1 is connected to the voltage line Lv2 via a branch line Lb1 and a branch line Lb3, and is connected to the voltage line Lv3 via a branch line Lb2. One end of the voltage line Lv2 is connected to the charging control unit 51, and the other end thereof is connected to the control unit 2.

Also, in the insertion state st1 where the charging plug 55 has been inserted in the connection part 5, the voltage line Lv1 is connected to the power line Lp2 via the branch line Lb3, and is connected to the voltage line Lv3 via the branch line Lb2. Further, on the charging equipment (50) side of the voltage line Lv2, an observation point P1 including a resistor R1 is set.

The charging equipment 50 detects the connection state with the battery device 1 by monitoring the voltage at the observation point P1 on the voltage line Lv2. In other words, the voltage line Lv2 is a line which the voltage to be used to detect the connection state by the charging equipment 50 is applied.

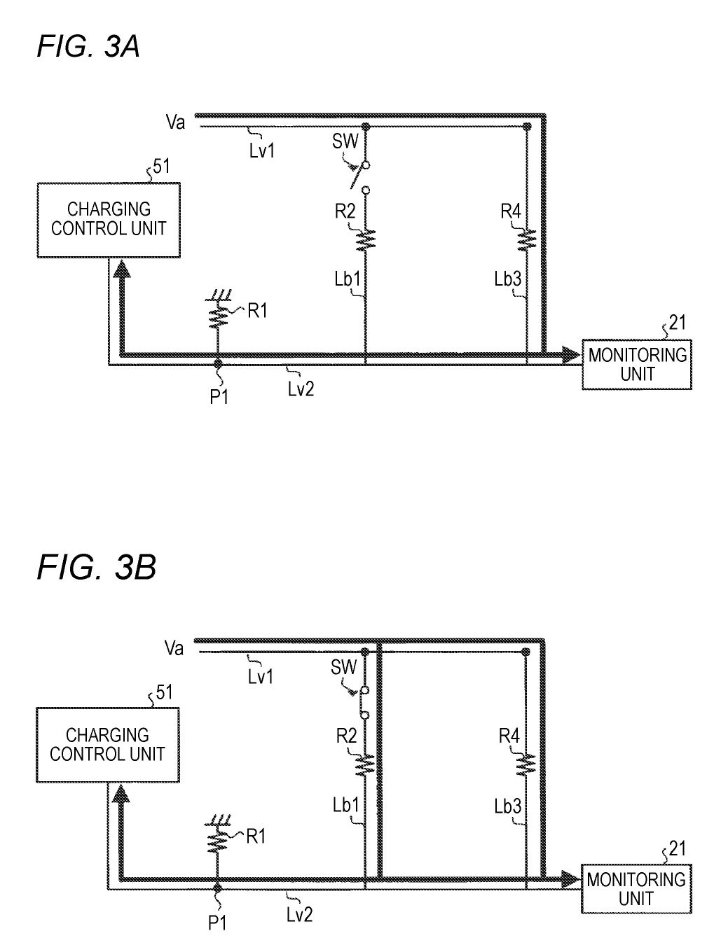

Also, in the present embodiment, since one end of the voltage line Lv2 is connected to the control unit 2, it becomes possible to detect the above-mentioned connection state by the control unit 2. The relation between the connection state and the voltage which is applied to the voltage line Lv2 will be described below with reference to FIG. 3A and FIG. 3B.

The voltage line Lv3 is a line whose one end is connected to the control unit 2 and which the control unit 2 uses to detect connection of the charging plug 55 with the connection part 5, and has an observation point P2 including a resistor R5, on the battery device (1) side.

If the charging plug 55 and the connection part 5 are connected, the predetermined voltage is applied from the voltage line Lv1 to the voltage line Lv3; whereas if the charging plug 55 and the connection part 5 are disconnected, the predetermined voltage is interrupted. In other words, on the observation point P2, it is possible to detect whether the charging plug 55 and the connection part 5 have been connected.

As described above, in the charging system 100 according to the present embodiment, on the battery device (1) side, it is possible to detect the connection state, using the voltage line Lv2. Therefore, it is possible to omit the voltage line Lv3.

One end of each of the signal line Lc1 and the signal line Lc2 is connected to the charging control unit 51, and the other end thereof is connected to the control unit 2. The signal line Lc1 and the signal line Lc2 are lines which the battery device 1 and the charging equipment 50 use to transmit and receive signals by CAN (Controller Area Network) communication.

For example, the charging control unit 51 transmits signals, such as a signal representing the current charged state, to the control unit 2 via the signal line Lc1 and the signal line Lc2. Also, the charging control unit 51 transmits an end notification representing the end of charging to the control unit 2 via the signal line Lc1 and the signal line Lc2.

However, as described above, some charging equipments 50 do not necessarily send an end notification. For this reason, the battery device 1 according to the present embodiment is required to detect the end of charging on the battery device (1) side.

Also, even in the case where the signal line Lc1 and the signal line Lc2 are broken, the battery device 1 cannot acquire the above-mentioned end notification from the charging equipment 50. For this reason, even in the case where the signal line Lc1 and the signal line Lc2 are broken, the present invention is useful.

One end of each of the auxiliary power line La1 and the auxiliary power line La2 is connected to an auxiliary power source 52, and the other end thereof is connected to the control unit 2. For example, to the auxiliary power line La1 and the auxiliary power line La2, a predetermined voltage is applied from the auxiliary power source 52.

Also, as shown in FIG. 2, the auxiliary power line La1 has a relay K3 on the charging equipment (50) side, and the auxiliary power line La2 has a relay K4 on the charging equipment (50) side.

Each of the relay K3 and the relay K4 is switched on and off by the charging control unit 51. For example, if the charging control unit 51 detects the above-mentioned lock state st2 (see FIG. 1), it switches the relay K3 and the relay K4 from the OFF state to the ON state.

As a result, the voltage is applied from the auxiliary power source 52 to the control unit 2 via the auxiliary power line La1 and the auxiliary power line La2. Also, when finishing charging a battery B, the charging control unit 51 switches the relay K3 and the relay K4 from the ON state to the OFF state. As a result, the connection between the auxiliary power source 52 and the control unit 2 by the auxiliary power line La1 and the auxiliary power line La2 is interrupted.

Now, the configuration of the charging equipment 50 will be described. The charging equipment 50 includes the charging control unit 51, the auxiliary power source 52, an AC-to-DC converter 53, an DC-to-DC converter 54, and the charging plug 55.

The charging control unit 51 controls the whole of the charging equipment 50. As described above, the charging control unit 51 detects the connection state between the charging plug 55 and the connection part 5 on the basis of the connection voltage applied to the voltage line Lv2.

In the case where the connection state has become the above-mentioned lock state st2, the charging control unit 51 performs control to switch the relays K1 to K4 from the OFF state to the ON state. Also, after starting charging, the charging control unit 51 transmits a signal representing the current charged state to the control unit 2 via the signal line Lc1 and the signal line Lc2.

Then, if charging is completed, the charging control unit 51 switches off the relay K1 and the relay K2, thereby stopping charging the battery device 1, while switching off the relay K3 and the relay K4.

As described above, if finishing charging of the battery B, the charging control unit 51 switches off the relay K3 and the relay K4. As a result, the auxiliary power line La1 and the auxiliary power line La2 are interrupted. Therefore, it is possible to detect the completion of the charging by the control unit 2.

However, if the user pulls out the charging plug 55 when the battery B is being charged in the state where the relay K3 and the relay K4 are in the ON state, the control unit 2 cannot detect the end of charging, using the auxiliary power line La1 and the auxiliary power line La2.

In contrast with this, in the present embodiment, since unlocking which is performed when the user pulls out the charging plug 55 is detected, it is possible to detect the end of charging before the charging plug 55 is pulled out by the user.

The auxiliary power source 52 is, for example, a storage battery for storing electric power for charging the battery B. The auxiliary power source 52 is connected to the AC-to-DC converter 53, for example, via a jumper.

AC power which is supplied from the auxiliary power source 52 is converted into DC power by the AC-to-DC converter 53, and the DC power is supplied to the DC-to-DC converter 54 via a coil provided in the AC-to-DC converter 53.

The DC-to-DC converter 54 adjusts the DC voltage which is supplied from the AC-to-DC converter 53, to a predetermined voltage (for example, 12 V), and applies the predetermined voltage to the battery B and the voltage line Lv1.

The battery device 1 includes the control unit 2, the connection part 5, and the battery B. The battery B is, for example, a storage battery having low charge/discharge efficiency, such as a lead battery. Electric power stored in the battery B is used as a power source for the vehicle C.

Also, the control unit 2 includes a monitoring unit 21 and a detecting unit 22. The control unit 2 includes a computer having, for example, a CPU (Central Processing Unit), a ROM (Read Only Memory), a RAM (Random Access Memory), an HDD (Hard Disk Drive), input/output ports, and so on, and various circuits.

The CPU of the computer functions as the monitoring unit 21 and the detecting unit 22 of the control unit 2, for example, by reading a program from the ROM and executing the program.

Also, it is possible to configure one or all of the monitoring unit 21 and the detecting unit 22 of the control unit 2 with hardware such as an ASIC (Application Specific Integrated Circuit), an FPGA (Field-Programmable Gate Array), and so on.

The monitoring unit 21 monitors the connection voltage varying gradually (for example, in a stepwise fashion) according to the connection state between the connection part 5 and the charging plug 55. Now, a specific example of a process which is performed by the monitoring unit 21 will be described with reference to FIG. 3A and FIG. 3B.

FIG. 3A and FIG. 3B are views illustrating specific examples of the connection state, and FIG. 3A shows the case where the connection state is the insertion state st1, and FIG. 3B shows the case where the connection state is the lock state st2. Also, in FIG. 3A and FIG. 3B, voltage flows are shown by thick arrows.

As shown in FIG. 3A, in the insertion state st1, although a voltage Va for monitoring, for example, 12 V which is applied to the voltage line Lv1 is applied to the voltage line Lv2 via the branch line Lb3, since the resistor R4 is on the branch line Lb3, the voltage Va for monitoring drops to a predetermined voltage (for example, 6V) due to the resistor R4, and the charging control unit 51 and the monitoring unit 21 detect the predetermined voltage.

For this reason, in the battery device 1, in the case where the monitoring unit 21 detects the voltage of 6V which is applied to the voltage line Lv2, it is possible to detect that the connection state is the insertion state st1.

Meanwhile, as shown in FIG. 3B, in the lock state st2, a switch SW provided on the branch line Lb1 is turned on. Therefore, in the lock state st2, the voltage line Lv1 and the voltage line Lv2 are electrically connected via the branch line Lb1 and the branch line Lb3.

Also, since the resistor R2 is on the branch line Lb1, the voltage Va for monitoring is divided by the branch line Lb1 and the branch line Lb3, and drops to a predetermined voltage (for example, 4 V) due to the resistor R2 and the resistor R4.

Therefore, in the battery device 1, in the case where the monitoring unit 21 detects the voltage of 4 V which is applied to the voltage line Lv2, it is possible to detect that the connection state is the lock state st2.

In this case, the switch SW is switched on or off, corresponding to an operation unit (not shown in the drawings) of the charging plug 55. Specifically, if the operation unit is operated in the insertion state st1, the charging plug 55 and the connection part 5 are mechanically locked while the switch SW is turned on.

Meanwhile, if the operation unit is operated in the lock state st2, the charging plug 55 and the connection part 5 are mechanically unlocked while the switch SW is turned off.

By the way, in the technology of the related art, the voltage line Lv2 is a line which the charging control unit 51 uses to monitor the connection state. Therefore, in the technology of the related art, the voltage line Lv2 is connected to the charging control unit 51; however, it is not connected to the monitoring unit 21.

In contrast with this, in the charging system 100 according to the embodiment, the voltage line Lv2 is connected to the monitoring unit 21. In other words, in the charging system 100 according to the embodiment, the charging equipment 50 monitors the voltage of the voltage line Lv2 provided for detecting the connection state, on the battery device (1) side.

As described above, in the charging system 100 according to the embodiment, since the voltage line Lv2 is shared by the charging equipment 50 and the control unit 2, it becomes possible to detect the connection state by both of the charging equipment 50 and the control unit 2.

In other words, in the charging system 100 according to the embodiment, it becomes possible to detect the end of charging, on the battery device (1) side, by the simply configuration which is obtained by extending the voltage line Lv2 to the monitoring unit 21. In short, it becomes possible to detect the end of charging, on the battery device (1) side, by the inexpensive configuration.

FIG. 2 will be further described with respect to the detecting unit 22 of the control unit 2. The detecting unit 22 detects the end of charging of the battery B on the basis of the connection voltage which is monitored by the monitoring unit 21.

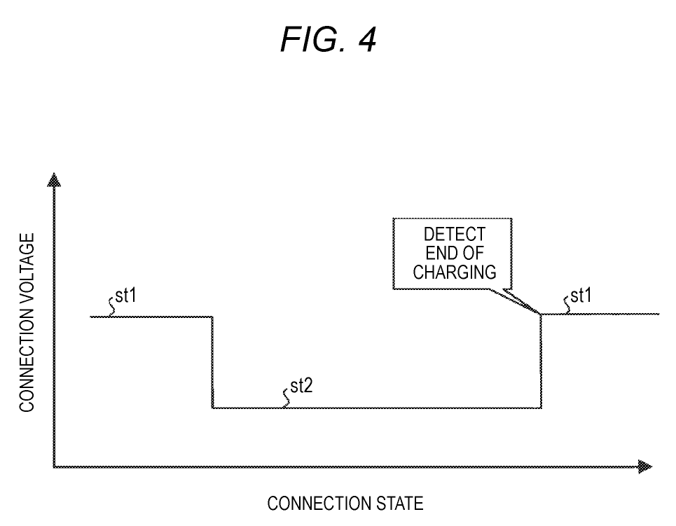

Now, the relation between the connection voltage and the connection state will be described with reference to FIG. 4. FIG. 4 is a view illustrating the relation between the connection voltage and the connection state. As described above, the connection voltage varies according to the connection state.

Specifically, as shown in FIG. 4, the connection voltage when the connection state is the insertion state st1 is higher than the connection voltage in the lock state st2. Also, as described above, in the case of starting charging, the connection state first transitions to the insertion state st1, and then transitions to the lock state st2, and in the case of finishing charging, the connection state transitions from the lock state st2 to the insertion state st1, and then the charging plug 55 is pulled out from the connection part 5.

In other words, after starting charging, in the case where the user pulls out the charging plug 55, the connection state transitions from the lock state st2 to the insertion state st1. Therefore, the detecting unit 22 detects the end of charging on the basis of change of the connection voltage according to unlocking.

Specifically, as shown in FIG. 4, if the connection voltage changes according to transition from the lock state st2 to the insertion state st1, the detecting unit 22 detects the end of charging.

In other words, the detecting unit 22 detects that the user has tried to pull out the charging plug 55, as the end of charging. In short, the detecting unit 22 detects the end of charging on the basis of change of the connection voltage according to unlocking. Therefore, it becomes possible to detect the end of charging before the user actually pulls out the charging plug 55.

Also, if detecting the end of charging, the detecting unit 22 switches off (interrupts) the relay K5 and the relay K6 connecting the battery B and the connection part 5 shown in FIG. 2.

As a result, the connection part 5 and the charging plug 55 are released from the high-voltage state, earlier than the charging plug 55 is actually pulled out. Therefore, it becomes possible to prevent the user from getting an electric shock due to contact with the connection part 5 and the charging plug 55.

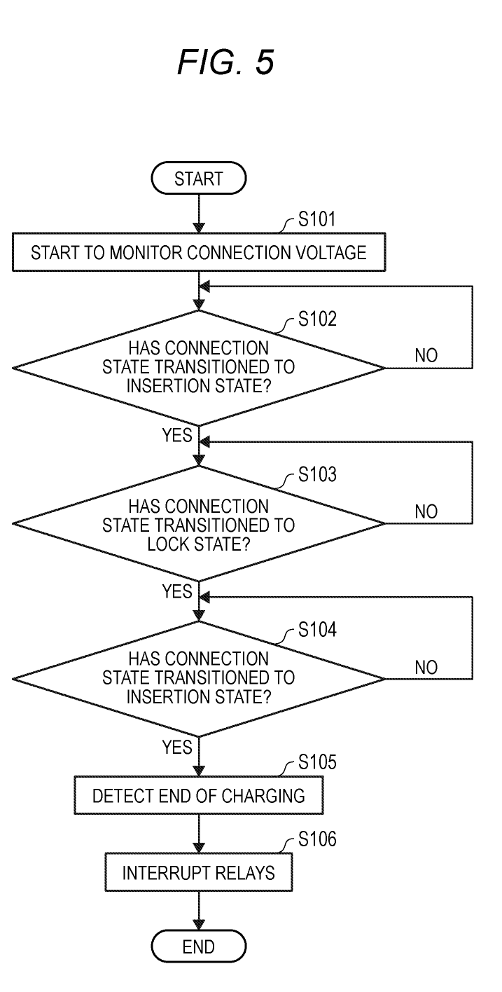

Now, the process procedure which is performed by the battery device 1 according to the embodiment will be described with reference to FIG. 5. FIG. 5 is a flow chart illustrating the process procedure which is performed by the battery device 1.

As shown in FIG. 5, first, the monitoring unit 21 of the control unit 2 starts to monitor the connection voltage (STEP S101). Subsequently, the detecting unit 22 determines whether the connection state has transitioned to the insertion state st1, on the basis of the connection voltage (STEP S102).

Here, the case where the connection state has not transitioned to the insertion state st1 (“No” in STEP S102) means that the charging plug 55 has not been connected to the connection part 5. Therefore, in this case, the detecting unit 22 carries on the process of STEP S102.

Meanwhile, in the case where the connection state has transitioned to the insertion state st1 (“Yes” in STEP S102), the detecting unit 22 determines whether the connection state has transitioned to the lock state st2 (STEP S103).

In the case where the connection state has not transitioned to the lock state st2 (“No” in STEP S103), the detecting unit 22 carries on the process of STEP S103. Meanwhile, in the case where the connection state has transitioned to the lock state st2 (“Yes” in STEP S103), the detecting unit 22 determines whether the connection state has transitioned from the lock state st2 to the insertion state st1 (STEP S104).

In the case where the connection state has not transitioned from the lock state st2 to the insertion state st1 (“No” in STEP S104), the detecting unit 22 carries on the process of STEP S104. Meanwhile, in the case where the connection state has transitioned from the lock state st2 to the insertion state st1 (“Yes” in STEP S104), the detecting unit 22 detects the end of charging (STEP S105).

Subsequently, the detecting unit 22 interrupts the relay K5 and the relay K6 connecting the connection part 5 and the battery B (STEP S106), and finishes the process.

As described above, the battery device 1 according to the embodiment includes the connection part 5, the monitoring unit 21, and the detecting unit 22. To the connection part 5, the charging plug 55 of the charging equipment 50 is connected. The monitoring unit 21 monitors the connection voltage varying in a stepwise fashion according to the connection state between the connection part 5 and the charging plug 55.

The detecting unit 22 detects the end of charging of the battery B on the basis of the connection voltage which is monitored by the monitoring unit 21. Therefore, the battery device 1 according to the embodiment can detect the end of charging.

In the above-described embodiment, the case where the connection state between the connection part 5 and the charging plug 55 has two stages has been described. However, the present invention is not limited thereto. In other words, the connection state may have three or more stages.

Also, in the above-described embodiment, the case where the control unit 2 shares the voltage line Lv2 with the charging equipment 50 has been described. However, the present invention is not limited thereto. For example, a line corresponding to the voltage line Lv2 may be separately provided for the control unit 2.

Additional advantages and modifications will readily occur to those skilled in the art. Therefore, the present invention in its broader aspects is not limited to the specific details and representative embodiment shown and described herein. Accordingly, various modifications may be made without departing from the spirit or scope of the general inventive concept as defined by the appended claims and their equivalents.

What is claimed is:

1. A battery device comprising:
a connection part to which a charging plug of charging equipment is connected;
a monitoring unit configured to monitor connection voltage varying gradually according to a connection state between the connection part and the charging plug; and
a detecting unit configured to detect an end of charging of a battery on the basis of the connection voltage which is monitored by the monitoring unit.

2. The battery device according to claim 1, wherein:
when detecting the end of charging, the detecting unit interrupts relays connecting the connection part and the battery.

3. The battery device according to claim 1, wherein:
the detecting unit detects the end of charging on the basis of change of the connection voltage according to unlocking of the charging plug and the connection part.

4. The battery device according to claim 2, wherein:
the detecting unit detects the end of charging on the basis of change of the connection voltage according to unlocking of the charging plug and the connection part.

5. The battery device according to claim 3, wherein:
the monitoring unit is connected to a voltage line to which voltage to detect the connection state by the charging equipment is applied, and monitors the connection voltage on the voltage line.

6. A charging end detecting method comprising:
a connecting step of connecting a charging plug of charging equipment;
a monitoring step of monitoring connection voltage varying gradually according to a connection state with the charging plug in the connecting step; and
a detecting step of detecting an end of charging of a battery on the basis of the connection voltage which is monitored by the monitoring step.
